(19) United States
(12) Patent Application Publication
(10) Pub. No.: US 2007/0132040 A1
(43) Pub. Date: Jun. 14, 2007

(54) SEMICONDUCTOR DEVICE AND METHOD FOR MANUFACTURING THE SAME

(75) Inventor: Shigeyuki Yokoyama, Chuo-Ku (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Chuo-ku (JP)

(21) Appl. No.: 11/566,628

(22) Filed: Dec. 4, 2006

(30) Foreign Application Priority Data
Dec. 8, 2005 (JP) 2005-354952
Aug. 28, 2006 (JP) 2006-230608

(51) Int. Cl. H01L 29/76

(52) U.S. Cl. 257/408

(57) ABSTRACT

A semiconductor device comprising a silicon substrate, a gate insulator provided on the silicon substrate, a gate electrode provided on the gate insulator, a first sidewall insulator provided on the side of the gate electrode, a second sidewall insulator provided on the first sidewall insulator, and source and drain diffusion regions, wherein the end of the gate insulator in the gate length direction is positioned immediately under the lower end of the first sidewall insulator in the gate electrode side surface direction, and the second sidewall insulator covers the end of the gate insulator.

### BACKGROUND OF THE INVENTION

1. Field of the Invention

The present invention relates to a semiconductor device and a method for manufacturing the same, and particularly to a semiconductor device with a MIS (Metal Insulator Semiconductor) type field effect transistor (MISFET) using a high-dielectric-constant material as a gate insulator and a method for manufacturing such a semiconductor device.

2. Description of the Related Art

In recent years, a MISFET used in a semiconductor integrated circuit device uses a thinner gate insulator as wiring (gate electrodes) becomes miniaturized.

The gate insulator of a conventional MISFET has been a silicon oxide film produced by thermal oxidation of a silicon substrate or a silicon oxynitride film produced by nitriding a silicon oxide film.

However, it has been difficult to further reduce the thickness of the silicon oxide film and silicon oxynitride film in a technological sense.

In recent years, developments have been made on a MISFET using a high-dielectric-constant film (high-k film) with relative permittivity higher than that of a silicon oxide film as the gate insulator. Use of such a high-dielectric-constant film allows a thicker physical film thickness that still provides the same relative permittivity as a silicon oxide film (silicon oxide-equivalent thickness).

A method for manufacturing a MISFET using a high-dielectric-constant film as the gate insulator will be described below with reference to the description in Japanese Patent Laid-Open No. 2003-101014.

Firstly, trenches are formed in the surface of a single crystal p-type silicon substrate 11. A silicon oxide film is formed by CVD such that it is buried in the trenches. Then, the excess portion of the silicon oxide film is removed to form element isolation regions 12, as shown in FIG. 4.

Subsequently, a ZrO₂ film 14, which is a high-dielectric-constant film, is formed as shown in FIG. 5 (the method for forming the ZrO₂ film will be described later in detail).

Thereafter, a polysilicon film 15 for forming a gate electrode on the ZrO₂ film 14 is formed by CVD as shown in FIG. 6.

Then, a photoresist pattern 16 is formed on the polysilicon film 15 as shown in FIG. 7.

Subsequently, the polysilicon film 15 is patterned by reactive ion etching using the photoresist pattern 16 as a mask to form a first gate electrode 15, as shown in FIG. 8.

Thereafter, arsenic ions are implanted, for example, at an acceleration voltage of 40 keV and a dose of 2×10¹⁵ cm⁻², followed by activating thermal treatment to concurrently form the following regions of high impurity concentration; an n+ gate electrode 15, n+ source region 17 and n+ drain region 18 (FIG. 8).

Then, a 300 nm-thick silicon oxide film is deposited over the surface by CVD to form an interlayer insulator 19. Subsequently, a photoresist pattern (not shown) for forming contact holes is formed on the interlayer insulator 19. The photoresist pattern is used as a mask to form contact holes in the interlayer insulator 19 by reactive ion etching. Finally, an Al film is sputtered over the surface and patterned to form a source electrode 20, drain electrode 21 and second gate electrode 22, and then an n-type MISFET is completed (FIG. 9).

In general, a MISFET has a structure called an LDD (Lightly Doped Drain). The LDD structure is formed by the steps of: firstly introducing an impurity at low concentration (forming a first diffusion layer) as shown in FIG. 10; then forming sidewall insulators 23 on the sides of the gate electrode 15 and introducing an impurity at high concentration using the sidewall insulators and the gate electrode as a mask as shown in FIG. 11 (forming a second diffusion layer (not shown)).

In the conventional method for manufacturing a MISFET, when a high-dielectric-constant film is used as the gate insulator, anisotropic dry etching is performed or the substrate is washed while the high-dielectric-constant film is exposed. If anisotropic dry etching is performed or the substrate is washed while the high-dielectric-constant film containing metal, such as a heavy metal, is exposed, the surface of the substrate and the apparatuses used in such processes may be undesirably contaminated by the metal.

In a process for manufacturing a MISFET having an LDD structure, the portion of the gate insulator that is not located under the gate electrode can be removed after the gate electrode was formed and the first impurity was introduced (after the process shown in FIG. 10), or after the sidewall insulators were formed. In this case, as it is difficult to remove the high-dielectric-constant film by dry etching, wet etching must be used for the removal.

When the unnecessary portion of the gate insulator is removed by wet etching after the first impurity was introduced (after the process shown in FIG. 10), the gate insulator under the gate electrode is also etched and side etched into the gate pattern (in the gate length direction). As a result, the breakdown voltage between the gate electrode and the substrate may be significantly reduced.

On the other hand, there is a semiconductor device having a SAC (Self Align Contact) structure in which a diffusion layer between a pair of FETs is shared, like a DRAM (Dynamic Random Access Memory) device. A problem when manufacturing such a semiconductor device will be described with reference to FIG. 3.

As shown in FIG. 3, a gate electrode 104 is formed on a silicon substrate 101, in which element isolation regions 102 are formed, via a gate insulator 103 made of a high-dielectric-constant film. Low-concentration impurity regions 105 that form an LDD structure are formed in the silicon substrate 101 by introducing an impurity using the gate electrode 104 as a mask.

Sidewall insulators 116 made of silicon nitride films are formed on the sides of the gate electrode 104 having an upper insulator 115, and a high-concentration impurity region 108 is formed using the gate electrode 104 and the sidewall insulators 116 as a mask. The unnecessary gate insulator 103 formed in the area that is not under the gate electrode is removed by wet etching after the high-concentration impurity region 108 was formed.

An interlayer insulator 120 is formed on the silicon substrate 101, and an hole 121 is formed in the interlayer insulator such that the hole 121 exposes a diffusion layer (the high-concentration impurity region 108) shared by a pair of MISFETs. A conductive material is buried in this hole to form a contact plug. When the SAC structure is formed, this hole has a diameter greater than or equal to the region of the diffusion layer (having a distance between the sidewall insulators of the adjacent gate electrodes), so that ends of the gate insulators 103 are exposed in the hole.

If the ends of the gate insulators 103 are exposed in the hole, in various processes, such as a process of forming the hole, a washing process after the hole was formed, and a process of burying a conductive material in the hole, the apparatuses used in such processes and the surface of the interlayer insulator can be contaminated by metal originating from the high-dielectric-constant material of the gate insulator.

### SUMMARY OF THE INVENTION

An object of the present invention is to provide a semiconductor device having a structure that can ensure a sufficient breakdown voltage between the gate electrode and the substrate and prevent contamination resulting from the gate insulator during manufacture and a method for manufacturing such a semiconductor device.

According to the present invention, there are provided the following semiconductor devices and methods for manufacturing the same.
(1) A semiconductor device comprising:

a silicon substrate; a gate insulator provided on the silicon substrate;
a gate electrode provided on the gate insulator;
a first sidewall insulator provided on the side of the gate electrode;
a second sidewall insulator provided on the first sidewall insulator; and
source and drain diffusion regions, wherein
the end of the gate insulator in the gate length direction is positioned immediately under the lower end of the first sidewall insulator in the gate electrode side surface direction, and
the second sidewall insulator covers the end of the gate insulator.
(2) The semiconductor device according to item 1, wherein
   the end of the gate insulator is positioned inside the upper surface of the first sidewall insulator in the thickness direction and an indentation is formed such that its inner wall is formed by the end of the gate insulator, the silicon substrate and the lower end of the first sidewall insulator, and
   the second sidewall insulator is formed so as to fill the indentation with the second sidewall insulator.
(3) The semiconductor device according to item 1 or 2, further comprising an interlayer insulator and a contact plug that connects to the source or drain diffusion region, wherein
   the contact plug is formed by forming an hole in the interlayer insulator such that it exposes the first sidewall insulator and burying a conductive material in the hole.
(4) The semiconductor device according to any one of items 1 to 3, wherein the first sidewall insulator is made of silicon nitride and the second sidewall insulator is made of silicon oxide.
(5) The semiconductor device according to any one of items 1 to 4, wherein the gate insulator is a high-dielectric-constant film.
(6) The semiconductor device according to item 5, wherein the high-dielectric-constant film is a metal oxide film or a metal oxynitride film.
(7) A method for manufacturing a semiconductor device, comprising the steps of:
   forming a gate insulator on a silicon substrate;
   forming a gate electrode on the gate insulator;
   forming a first diffusion region by introducing an impurity into the silicon substrate using the gate electrode as a mask;
   forming a first sidewall insulator on the side of the gate electrode;
   performing isotropic etching such that the end of the gate insulator in the gate length direction is positioned immediately under the lower end of the first sidewall insulator in the gate electrode side surface direction;
   forming a second sidewall insulator on the first sidewall insulator such that the second sidewall insulator covers the end of the gate insulator; and
   forming a second diffusion region having a concentration higher than that of the first diffusion region by introducing an impurity using the gate electrode, the first sidewall insulator and the second sidewall insulator as a mask.
(8) The method for manufacturing a semiconductor device according to item 7, wherein
   in the step of performing isotropic etching, the etching time is controlled to control the amount of side etching of the gate insulator in order to position the end of the gate insulator inside the upper surface of the first sidewall insulator in the thickness direction and form an indentation whose inner wall is formed by the end of the gate insulator, the silicon substrate and the lower end of the first sidewall insulator, and
   in the step of forming a second sidewall insulator, a second sidewall insulator is formed so as to fill the indentation with the second sidewall insulator.
(9) The method for manufacturing a semiconductor device according to item 7 or 8, wherein
   in the step of forming a gate electrode, a gate electrode having an insulating layer thereon is formed, and
   the method further comprising the steps of:
   forming an interlayer insulator after the second diffusion region was formed;
   forming an hole in the interlayer insulator such that the hole reaches the second diffusion region and exposes the first sidewall insulator; and
   burying a conductive material in the hole to form a contact plug.
(10) The method for manufacturing a semiconductor device according to item 7 or 8, wherein
   in the step of forming a gate electrode, a plurality of gate electrodes arranged adjacent to each other in a same active region are formed, each gate electrode having an insulating layer thereon, and
   in the step of forming a second diffusion region, a second diffusion region is formed between adjacent gate electrodes, and
   the method further comprising the steps of:
   forming an interlayer insulator after the second diffusion region is formed;
   forming an hole having an inner diameter greater than the distance between adjacent gate electrodes such that the hole reaches the second diffusion region between the gate electrodes; and
   burying a conductive material in the hole to form a contact plug.
(11) The method for manufacturing a semiconductor device according to any one of items 7 to 10, wherein the first sidewall insulator is made of silicon nitride and the second sidewall insulator is made of silicon oxide.
(12) The method for manufacturing a semiconductor device according to any one of items 7 to 11, wherein the gate insulator is a high-dielectric-constant film.
(13) The method for manufacturing a semiconductor device according to item 12, wherein the high-dielectric-constant film is a metal oxide film or a metal oxynitride film.
(14) The method for manufacturing a semiconductor device according to any one of items 7 to 13, wherein the isotropic etching is wet etching.

According to the present invention, there are provided a semiconductor device having a structure that can ensure a sufficient breakdown voltage between the gate electrode and the substrate and prevent contamination resulting from the gate insulator during manufacture and a method for manufacturing such a semiconductor device.

### BRIEF DESCRIPTION OF THE DRAWINGS

FIGS. 1(A) to 1(D) are diagrammatic process cross-sectional views illustrating a method for manufacturing the semiconductor device according to the present invention;

FIGS. 2(A) to 2(C) are diagrammatic partial cross-sectional views for explaining the semiconductor device according to the present invention;

FIG. 3 is a diagrammatic cross-sectional view for explaining a problem associated with a method for manufacturing a conventional semiconductor device;

FIG. 4 is a diagrammatic cross-sectional view for explaining the method for manufacturing the conventional semiconductor device;

FIG. 5 is a diagrammatic cross-sectional view for explaining the method for manufacturing the conventional semiconductor device;

FIG. 6 is a diagrammatic cross-sectional view for explaining the method for manufacturing the conventional semiconductor device;

FIG. 7 is a diagrammatic cross-sectional view for explaining the method for manufacturing the conventional semiconductor device;

FIG. 8 is a diagrammatic cross-sectional view for explaining the method for manufacturing the conventional semiconductor device;

FIG. 9 is a diagrammatic cross-sectional view for explaining the method for manufacturing the conventional semiconductor device;

FIG. 10 is a diagrammatic cross-sectional view for explaining the method for manufacturing the conventional semiconductor device; and

FIG. 11 is a diagrammatic cross-sectional view for explaining the method for manufacturing the conventional semiconductor device.

### DETAILED DESCRIPTION OF THE PREFERRED EMBODIMENTS

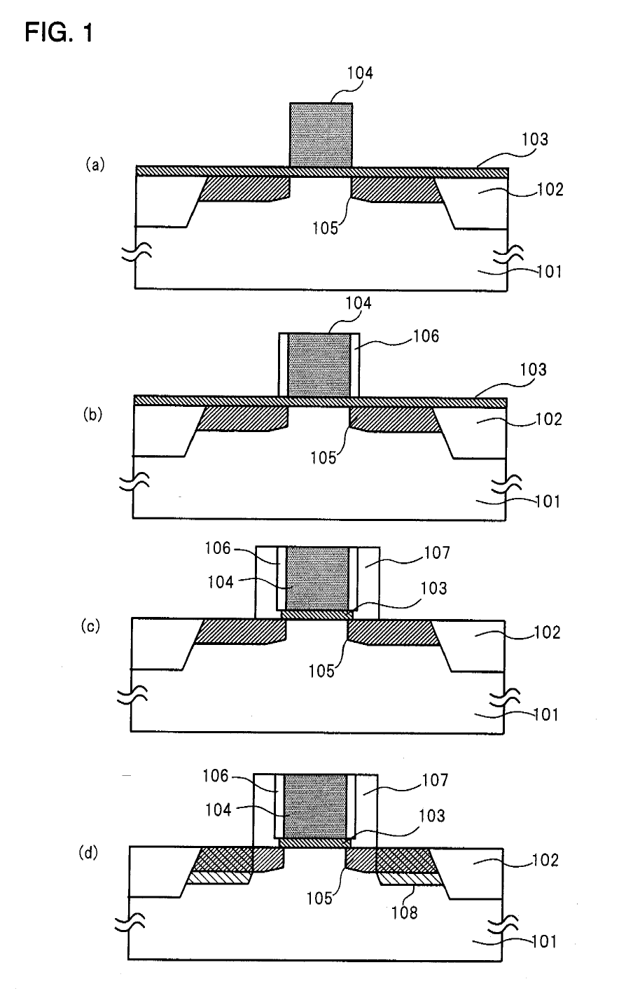

A preferred embodiment of the present invention will be described in detail with reference to FIGS. 1(A) to 1(D), which is a diagrammatic process cross-sectional view.

Firstly, a silicon substrate 101 is prepared. The silicon substrate 101 is provided with an element isolation region 102 that isolates an element region (active region).

A gate insulator 103 made of an 8 nm-thick high-dielectric-constant film (having a silicon oxide-equivalent thickness of 2 nm) is formed on the silicon substrate 101.

Then, a 100 nm-thick polysilicon film is formed by CVD (Chemical Vapor Deposition). The polysilicon film is patterned by typical lithography and dry etching technologies to form a gate electrode 104. To detect termination of dry etching, the gate insulator 103 can be used as a termination detection layer.

The gate electrode is used as a mask to introduce an impurity by ion implantation to form a shallow region with the impurity at low concentration (low-concentration impurity region) 105 (FIG. 1(A)).

As a material of the high-dielectric-constant film (hereinafter referred to as “high-k film”), materials having relative permittivity higher than that of silicon oxide (SiO₂) (hereinafter referred to as “high-k material”) can be used.

Examples of the high-k material include oxide and nitride containing at least one element selected from the group consisting of strontium (Sr), aluminum (Al), magnesium (Mg), scandium (Sc), gadolinium (Gd), yttrium (Y), samarium (Sm), hafnium (HfO, zirconium (Zr), tantalum (Ta), lanthanum (La), barium (Ba) and bismuth (Bi). Specific examples are strontium oxide (SrO) having a relative permittivity of about 6, aluminum oxide (Al₂O₃) having a relative permittivity of about 8, magnesium oxide (MgO) having a relative permittivity of about 10, scandium oxide (Sc₂O₃) or gadolinium oxide (Gd₂O₃) having a relative permittivity of about 14, yttrium oxide (Y₂O₃) or samarium oxide (Sm₂O₃) having a relative permittivity of about 16, hafnium oxide (HfO₂) or zirconium oxide (ZrO₂) having a relative permittivity of about 22, tantalum oxide (Ta₂O₅) having a relative permittivity of about 25, barium oxide (BaO) having a relative permittivity of about 35, bismuth oxide (Bi₂O₃) having a relative permittivity of about 40, ternary compounds, such as a hafnium aluminate film (HfAlO) and hafnium silicate (HfSiO), and their nitride counterparts. The high-k film made of these materials may be a single layer or a complex film in which two or more films are stacked.

Among them, hafnium oxide (HfO₂) or zirconium oxide (ZrO₂), or their metal-containing analogues, i.e., metal oxides containing silicon (Si) or aluminum (Al) (HfSiO, ZrSiO, HfAlO and ZrAlO), or their metal and nitrogen-containing analogues, i.e., metal oxynitride containing nitrogen (N) (such as HfSiON) may be preferably used. In terms of heat resistance and relative permittivity, HfSiO and HfSiON are preferable, and HfSiON is particularly preferable.

In this embodiment, an HfSiON film is formed as the high-k film. As the HfSiON film, a typical HfSiON film described in, for example, Japanese Patent Laid-Open No. 2005-79223 and Japanese Patent Laid-Open No. 2004-165553 can be used and formed according to a method described, for example, in Japanese Patent Laid-Open No. 2005-79223.

Then, a 10 nm-thick silicon nitride film is deposited and etched back by anisotropic dry etching to form 10 nm-thick first sidewall insulators 106 on the sides of the gate electrode (FIG. 1(B)).

Thereafter, the unnecessary portion of the gate insulator 103 that is exposed on the substrate surface is removed by wet etching.

This wet etching can be carried out at room temperature by using hydrofluoric acid aqueous solution (HF:H₂O=1:500 by weight).

In this wet etching process, the wet etching time is controlled such that the gate insulator immediately under the gate electrode 104 will not be removed.

In the structure of this embodiment, the gate insulator immediately under the gate electrode 104 remains intact, while the exposed portion of the gate insulator can be completely removed by controlling the etching time in seconds in the above wet etching process and terminating the etching process in 800 seconds. Consequently, as shown in FIG. 1(C), the end of the gate insulator 103 in the gate length direction can be positioned immediately under the lower end of the first sidewall insulator 106. The lower end of the first sidewall insulator means the downward (substrate side) end in the gate electrode side surface direction (in the side surface plane direction).

Then, a 50 nm-thick silicon oxide film is deposited and etched back by anisotropic dry etching to form 50 nm-thick second sidewall insulators 107 made of a silicon oxide film on the outside of the already-formed first sidewall insulators 106 made of the silicon nitride film (FIG. 1(C)). In this process, the second sidewall insulator is formed such that it is directly in contact with and covers the exposed end of the gate insulator without any exposed part thereof.

Thereafter, the gate electrode and the first and second sidewall insulators are used as a mask to introduce an impurity by ion implantation to form a deep region containing the impurity at high concentration (high-concentration impurity region) 108 (FIG. 1(D)).

After an interlayer insulator is formed over the surface, holes that expose the high-concentration impurity region and the like are formed. A conductive material is buried in these holes to form contact plugs. These plugs are connected with wirings in the upper layer and one of the electrodes of a capacitive element in the upper layer.

To form a SAC structure, a gate electrode with a silicon nitride film thereon is preferably formed by the steps of forming a silicon nitride film on the polysilicon film, patterning the silicon nitride film by dry etching using a photoresist as a mask and patterning the polysilicon film by dry etching using the patterned silicon nitride film as a mask. Even when a contact hole that overlaps with the gate pattern is formed and a conductive material is buried in the contact hole to form a plug, the silicon nitride film formed on the gate electrode and the first sidewall insulators formed on the sides of the gate electrode can insulate the plug from the gate electrode.

In this embodiment in which the first sidewall insulator is made of a silicon nitride film and the second sidewall insulator is made of a silicon oxide film, when a contact hole that overlaps with the gate pattern is formed, the first sidewall insulator is exposed in the contact hole, so that the plug formed by burying the conductive material in the hole comes into contact with the first sidewall insulator. When the contact hole has an inner diameter larger than the distance between the gate electrodes adjacent to each other in a same active region, the above structure is likely to be employed. Even when such a SAC structure is formed, the present invention can prevent contamination resulting from the high-k material of the gate insulator during manufacture.

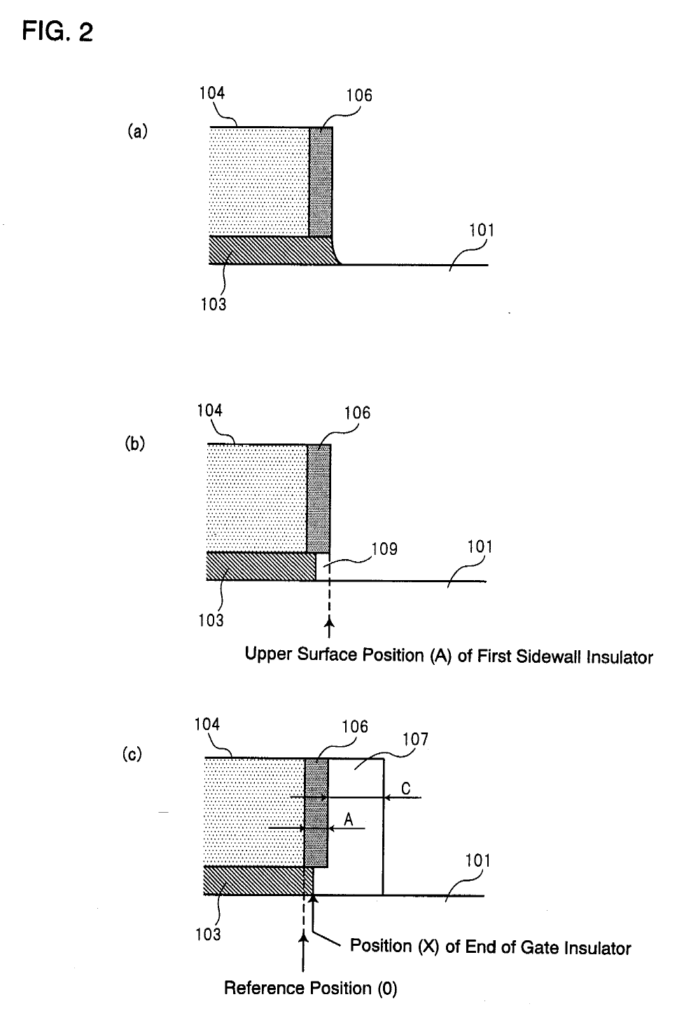

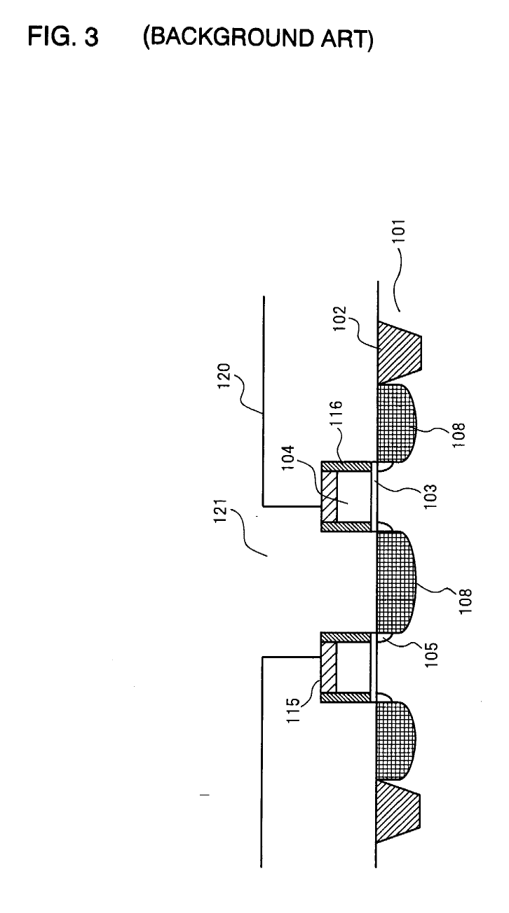

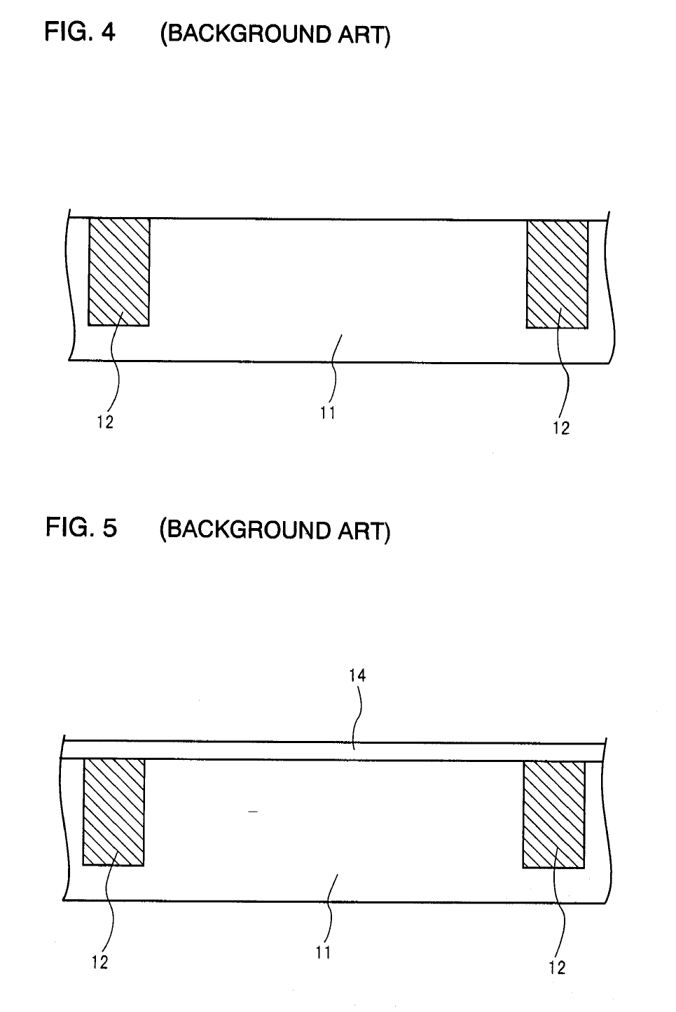

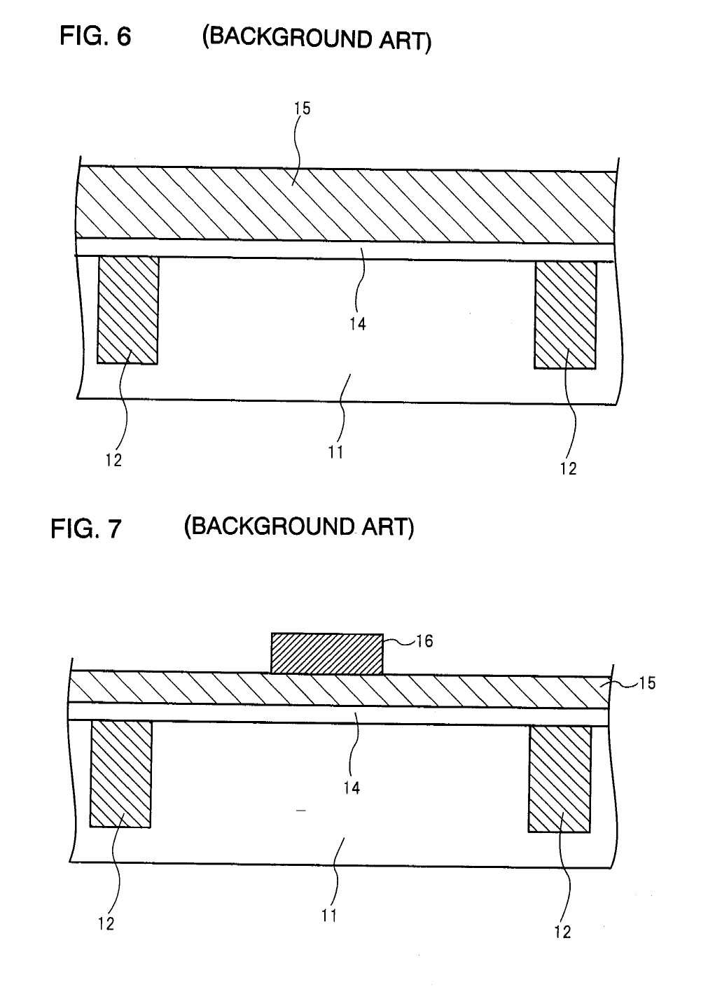

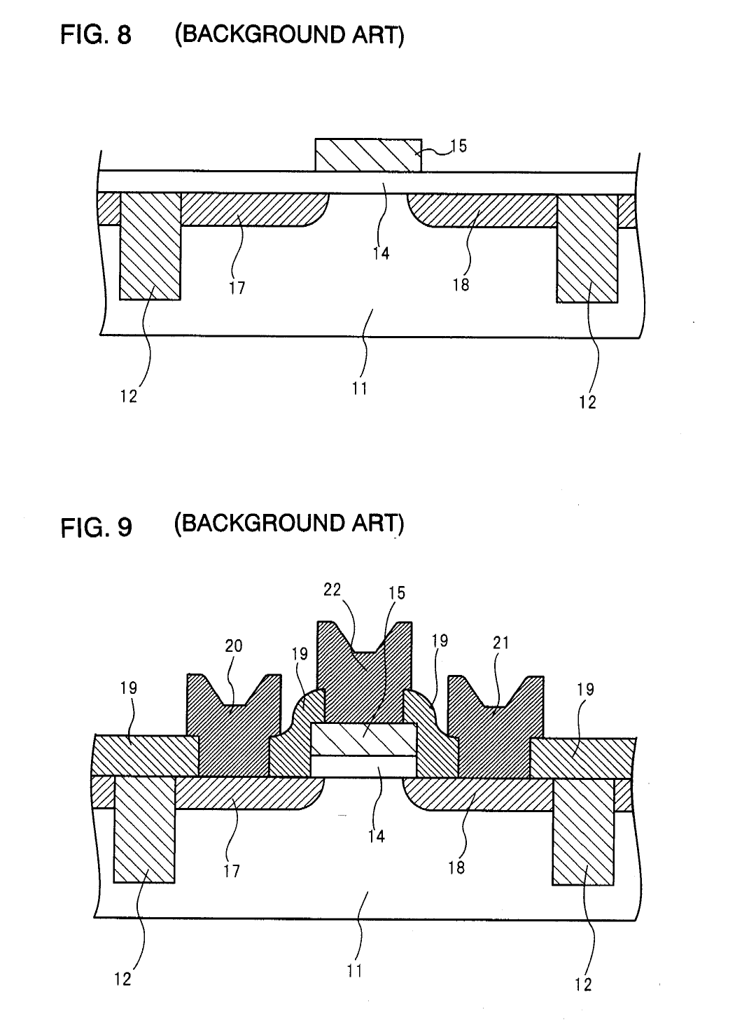

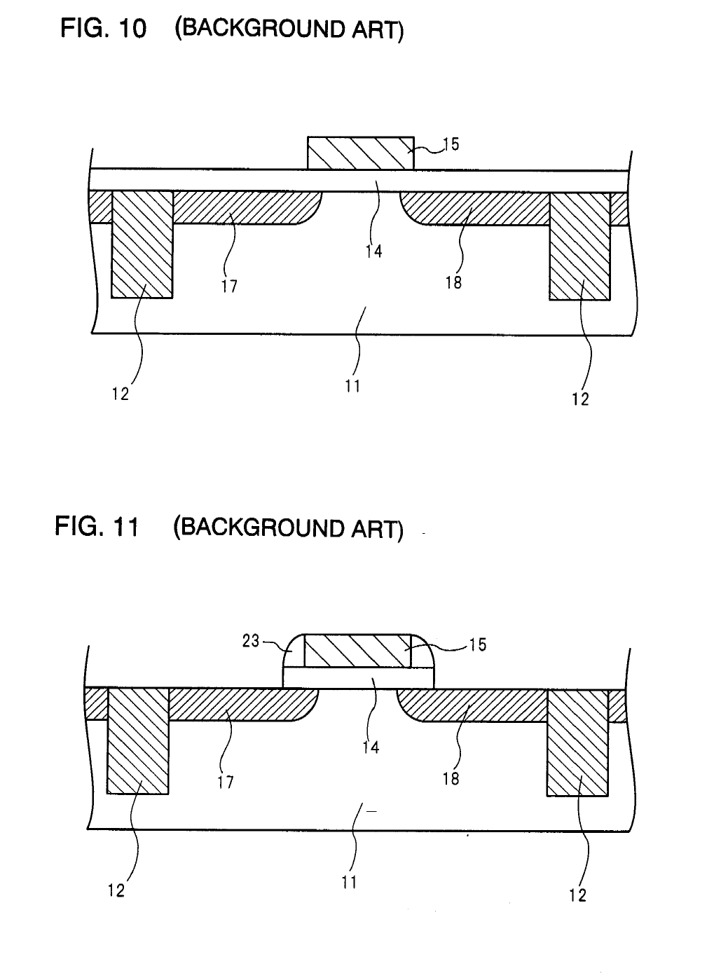

FIGS. 2(A) to 2(C) are diagrammatic partial cross-sectional views of the lower part of the gate electrode. FIGS. 2(A) and 2(B) show the lower part of the gate electrode after the first sidewall insulator 106 was formed and before the second sidewall insulator 107 is formed. FIG. 2(C) shows the lower part of the gate electrode after the first sidewall insulator 106 and the second sidewall insulator 107 were formed.

In the process of removing the unnecessary portion of the gate insulator 10 by wet etching, when the adhesion between the gate insulator 103 and the silicon substrate 101 is high and the etching is terminated when the end of the upper surface of the gate insulator 103 is flush with the upper surface of the first sidewall insulator 106 in the thickness direction as shown in FIG. 2(A), the lower side (silicon substrate side) of the gate insulator is less side etched than the upper side. Therefore, the gate insulator often remains outside the upper surface of the first sidewall insulator in the thickness direction (that is, outside the “upper surface position (A) of the first sidewall insulator”). If a contact hole is formed under such a condition, especially when the SAC structure is formed, the remaining gate insulator mentioned above is likely exposed in the contact hole. Therefore, the end of the lower surface of the gate insulator is preferably inside the upper surface position (A) of the first sidewall insulator.

The end of the gate insulator means the end in the gate length direction, and the thickness direction of the first sidewall insulator means the direction perpendicular to the side of the gate electrode. The upper surface position (A) of the first sidewall insulator refers to the intersection between the plane including the upper surface (the right end surface in FIG. 2(B)) of the first sidewall insulator in the thickness direction (the extended plane of the upper surface, which corresponds to the dotted line in FIG. 2(B)) and the upper surface of the silicon substrate.

FIG. 2(B) diagrammatically shows that the end of the gate insulator 103 is inside the upper surface of the first sidewall insulator in the thickness direction (that is, inside the upper surface position (A) of the first sidewall insulator). An indentation 109 is formed with respect to the upper surface of the first sidewall insulator. The inner wall of the indentation is formed of the end of the gate insulator, the lower end of the first sidewall insulator in the direction of the gate electrode side surface, and the upper surface of the silicon substrate.

When the second sidewall insulator 107 is formed (FIG. 1(C)), the end of the gate insulator 103 is covered by the second sidewall insulator 107. In this process, the indentation 109 is filled with the second sidewall insulator 107, as shown in FIG. 2(C).

The position (X) of the end of the gate insulator after the wet etching preferably satisfies A>X>0, where A (nm) is the thickness of the silicon nitride film that forms the first sidewall insulator 106 (the thickness in the direction perpendicular to the side surface of the gate electrode), and the reference position (0) is the position of the nearest side surface of the gate electrode (let the positive side be the side where the first sidewall insulator is formed). This can be achieved by positioning the end of the gate insulator immediately under the lower end of the first sidewall insulator 106. The reference position (0) herein is the intersection between the plane including the side surface of the gate electrode (the extended plane of the side surface, which corresponds to the dotted line in FIG. 2(C)) and the upper surface of the silicon substrate.

The position X of the end of the gate insulator is preferably smaller than A (A>X). When the SAC structure is formed and the position X is greater than or equal to A (A≦X), the end of the gate insulator can be exposed in the contact hole.

In the process of forming the contact hole by anisotropic dry etching after the interlayer insulator was formed, the position X of the end of the gate insulator immediately under the lower end of the first sidewall insulator 106 preferably satisfies the formula 1.

$$\begin{matrix}[ Formula 1 ] & \\ X < A - ( \frac{T g}{V v} + k ) \times V h & ( 1 )\end{matrix}$$

where Vv (nm/min) is the etching rate of the interlayer insulator in the direction perpendicular to the substrate, Vh (nm/min) is the etching rate of the second sidewall insulator in the direction parallel to the substrate, Tg (nm) is the film thickness of the interlayer insulator, and k (min) is the overetching time.

It is preferable that the end of the gate insulator is immediately under the lower end of the first sidewall insulator 106 and the position X of the end of the gate insulator is outside the reference position (0) (X>0).

The low-concentration impurity region 105 of the LDD structure is thermally treated for impurity activation so that it diffuses into the gate electrode side, ensuring a sufficient breakdown voltage if X>0.

On the other hand, if A>X, as shown in FIG. 2(B), the end of the gate insulator is recessed inside the upper surface position (A) of the first sidewall insulator, so that the indentation 109 whose bottom is the end of the gate insulator is formed. When the second sidewall insulator is formed, the indentation 109 is filled with the insulator. Considering that the depth of the indentation (the length from the position (X) of the end of the gate insulator to the upper surface position (A) of the first sidewall insulator) becomes greatest at X=0, in order to sufficiently bury the second sidewall insulator in the indentation, the relationship between the thickness A of the first sidewall insulator 106 and the thickness C of the second sidewall insulator 107 preferably satisfies A≦0.3C, more preferably A≦0.25C.

That is, the thickness C of the second sidewall insulator 107 is set to be sufficiently thicker than the thickness A of the first sidewall insulator 106, or the second sidewall insulator is formed such that the thickness A is preferably 30% of the thickness C or smaller, more preferably 25% or smaller, allowing the indentation 109 to be filled with the second sidewall insulator without forming any void.

By thus filling the indentation with the second sidewall insulator, when the contact hole is formed by anisotropic dry etching, even if the first sidewall insulator is exposed in the contact hole, the end of the gate insulator will not be exposed because it is covered by the second sidewall insulator in the indentation. As a result, in various processes, such as a process of forming the contact hole, a washing process after the contact hole was formed, and a process of burying a conductive material in the contact hole, contamination resulting from the high-k material of the gate insulator can be prevented.

In this embodiment, although a silicon nitride film is used as the first sidewall insulator, films other than a silicon nitride film may be used as long as the film is hardly soluble in an etchant for the gate insulator, is etched slower than the interlayer insulator in the contact hole formation process, and has high etching selectivity.

In this embodiment, although a silicon oxide film is used as the second sidewall insulator in terms of manufacturability of the LDD structure, a silicon nitride film may be used as the second sidewall insulator considering that the exposure of the end of the gate insulator is largely prevented in the contact hole formation process.

What is claimed is:

1. A semiconductor device comprising:
a silicon substrate;
a gate insulator provided on the silicon substrate;
a gate electrode provided on the gate insulator;
a first sidewall insulator provided on the side of the gate electrode;
a second sidewall insulator provided on the first sidewall insulator; and
source and drain diffusion regions, wherein
the end of the gate insulator in the gate length direction is positioned immediately under the lower end of the first sidewall insulator in the gate electrode side surface direction, and
the second sidewall insulator covers the end of the gate insulator.

2. The semiconductor device according to claim 1, wherein
the end of the gate insulator is positioned inside the upper surface of the first sidewall insulator in the thickness direction and an indentation is formed such that its inner wall is formed by the end of the gate insulator, the silicon substrate and the lower end of the first sidewall insulator, and
the second sidewall insulator is formed so as to fill the indentation with the second sidewall insulator.

3. The semiconductor device according to claim 1, further comprising an interlayer insulator and a contact plug that connects to the source or drain diffusion region, wherein
the contact plug is formed by forming an hole in the interlayer insulator such that it exposes the first sidewall insulator and burying a conductive material in the hole.

4. The semiconductor device according to claim 1, wherein the first sidewall insulator is made of silicon nitride and the second sidewall insulator is made of silicon oxide.

5. The semiconductor device according to claim 1, wherein the gate insulator is a high-dielectric-constant film.

6. The semiconductor device according to claim 5, wherein the high-dielectric-constant film is a metal oxide film or a metal oxynitride film.

7. A method for manufacturing a semiconductor device, comprising the steps of:
forming a gate insulator on a silicon substrate;
forming a gate electrode on the gate insulator;
forming a first diffusion region by introducing an impurity into the silicon substrate using the gate electrode as a mask;
forming a first sidewall insulator on the side of the gate electrode;
performing isotropic etching such that the end of the gate insulator in the gate length direction is positioned immediately under the lower end of the first sidewall insulator in the gate electrode side surface direction;
forming a second sidewall insulator on the first sidewall insulator such that the second sidewall insulator covers the end of the gate insulator; and
forming a second diffusion region having a concentration higher than that of the first diffusion region by introducing an impurity using the gate electrode, the first sidewall insulator and the second sidewall insulator as a mask.

8. The method for manufacturing a semiconductor device according to claim 7, wherein
in the step of performing isotropic etching, the etching time is controlled to control the amount of side etching of the gate insulator in order to position the end of the gate insulator inside the upper surface of the first sidewall insulator in the thickness direction and form an indentation whose inner wall is formed by the end of the gate insulator, the silicon substrate and the lower end of the first sidewall insulator, and
in the step of forming a second sidewall insulator, a second sidewall insulator is formed so as to fill the indentation with the second sidewall insulator.

9. The method for manufacturing a semiconductor device according to claim 7, wherein
in the step of forming a gate electrode, a gate electrode having an insulating layer thereon is formed, and
the method further comprising the steps of:
forming an interlayer insulator after the second diffusion region is formed;
forming an hole in the interlayer insulator such that the hole reaches the second diffusion region and exposes the first sidewall insulator; and
burying a conductive material in the hole to form a contact plug.

10. The method for manufacturing a semiconductor device according to claim 7, wherein
in the step of forming a gate electrode, a plurality of gate electrodes arranged adjacent to each other in a same active region are formed, each gate electrode having an insulating layer thereon, and
in the step of forming a second diffusion region, a second diffusion region is formed between adjacent gate electrodes, and
the method further comprising the steps of:
forming an interlayer insulator after the second diffusion region is formed;
forming an hole having an inner diameter greater than the distance between adjacent gate electrodes such that the hole reaches the second diffusion region between the gate electrodes; and
burying a conductive material in the hole to form a contact plug.

11. The method for manufacturing a semiconductor device according to claim 7, wherein the first sidewall insulator is made of silicon nitride and the second sidewall insulator is made of silicon oxide.

12. The method for manufacturing a semiconductor device according to claim 7, wherein the gate insulator is a high-dielectric-constant film.

13. The method for manufacturing a semiconductor device according to claim 12, wherein the high-dielectric-constant film is a metal oxide film or a metal oxynitride film.

14. The method for manufacturing a semiconductor device according to claim 7, wherein the isotropic etching is wet etching.
